(19) United States
(12) Patent Application Publication
(10) Pub. No.: US 2011/0192349 A1
(43) Pub. Date: Aug. 11, 2011

(54) Phase-Modulated RF Power for Plasma Chamber Electrode

(76) Inventors: Edward P. Hammond, IV, Hillsborough, CA (US); Tsutomu Tanaka, Santa Clara, CA (US); Christopher Boitnott, Half Moon Bay, CA (US); Jozef Kudela, Sunnyvale, CA (US)

(21) Appl. No.: 13/005,526

(22) Filed: Jan. 12, 2011

Related U.S. Application Data
(60) Provisional application No. 61/294,128, filed on Jan. 12, 2010.
(60) Provisional application No. 61/294,468, filed on Jan. 12, 2010.
(60) Provisional application No. 61/352,817, filed on Jun. 8, 2010.

(51) Int. Cl. C23C 16/509

(52) U.S. Cl. 118/723 E

(57) ABSTRACT

A plurality of RF power signals have the same RF frequency as a reference RF signal and are coupled to respective RF connection points on an electrode of a plasma chamber. At least three of the RF connection points are not collinear. At least two of the RF power signals have time-varying phase offsets relative to the reference RF signal that are distinct functions of time. Such time-varying phase offsets can produce a spatial distribution of plasma in the plasma chamber having better time-averaged uniformity than the uniformity of the spatial distribution at any instant in time.

### CROSS REFERENCE TO RELATED APPLICATIONS

This patent application claims the benefit of U.S. Provisional Application No. 61/294,128 filed Jan. 12, 2010; U.S. Provisional Application No. 61/294,468 filed Jan. 12, 2010; and U.S. Provisional Application No. 61/352,817 filed Jun. 8, 2010.

### TECHNICAL FIELD

The invention relates generally to coupling RF power to an electrode of a plasma chamber used to perform plasma processes for fabricating electronic devices such as semiconductors, displays, solar cells, and solid state light emitting devices. The invention relates more specifically to coupling RF power to different points on the electrode with different time-varying phase offsets, whereby the uniformity of such plasma processes typically can be improved.

### BACKGROUND ART

Plasma chambers commonly are used to perform plasma processes for fabricating electronic devices such as semiconductors, displays and solar cells. Such plasma fabrication processes include chemical vapor deposition of semiconductor, conductor or dielectric layers on the surface of a workpiece or etching of selected portions of such layers on the workpiece surface.

It is important for a plasma fabrication process to be performed with high spatial uniformity over the surface of the workpiece. For example, a deposition process should be performed so that the deposited material has uniform thickness and quality at all positions on the surface of the workpiece. Likewise, an etch process should etch material at a uniform rate at all such positions.

RF power can be capacitively coupled to plasma within a plasma chamber by coupling a source of RF power to an electrode positioned within, or adjacent to, the plasma chamber. If any dimension of the electrode is greater than approximately one-tenth the wavelength of the RF power in the plasma, the plasma density, and hence the plasma fabrication process being performed on the workpiece, typically will suffer spatial non-uniformity if the RF power is coupled to only a single point on the electrode. In such cases, spatial uniformity of the plasma process typically can be improved by coupling the RF power to a plurality of spatially distributed RF connection points on the electrode.

U.S. patent application Ser. No. 12/363,760 filed Jan. 31, 2009 by Stimson et al., having the same assignee as present application, discloses two or more RF connection points that are spatially distributed in two dimensions on an electrode of a plasma chamber, wherein different RF power signals having the same frequency and different phase offsets are coupled to different RF connection points. The phase offsets are disclosed as either fixed or time-varying.

U.S. provisional patent application No. 61/162,836 filed Mar. 24, 2009 by Baek, having the same assignee as present application, discloses two or more RF power signals of different frequencies coupled to different RF connection points that are spatially distributed in two dimensions on an electrode of a plasma chamber. The difference between the respective frequencies of the RF power signals is less than any of the RF power frequencies and produces an interference pattern.

### SUMMARY OF THE INVENTION

The apparatus and method of the present invention improves on the prior art by establishing different time-varying phase offsets among a plurality of RF power signals that have the same RF frequency as a reference RF signal. The respective RF power signals are coupled to respective RF connection points on an electrode of a plasma chamber. At least three of the RF connection points are not collinear.

In a first embodiment or aspect of the invention, at least two of the RF power signals have phase offsets relative to the reference RF signal that are distinct, periodic functions of time. Advantageously, such phase offsets produce an RF electric field in the plasma chamber having an instantaneous spatial distribution that varies over time. In other words, the instantaneous spatial distribution has maxima and minima at locations that shift spatially over time. The resulting spatial distribution of plasma in the plasma chamber generally has a better time-averaged uniformity than the uniformity of the spatial distribution at any instant in time.

In a second embodiment or aspect of the invention, at least two of the RF power signals have time-varying phase offsets relative to the reference RF signal that are distinct functions of time which are not required to be periodic. An additional RF power signal having a lower RF frequency also is coupled to the electrode of the plasma chamber. Advantageously, the RF power at the lower frequency can reinforce the plasma density at one or more locations where the instantaneous or time-averaged electric field produced by the RF power at the higher reference frequency is minimum.

### BRIEF DESCRIPTION OF THE DRAWINGS

FIG. 1 is a partially schematic, sectional side view of a plasma chamber according to the invention.

FIG. 2 is partially schematic, perspective view of a plasma chamber according to the invention.

FIG. 3 is partially schematic, perspective view of a plasma chamber according to the invention, with additional details of an exemplary implementation of the RF power sources.

### BEST MODE FOR CARRYING OUT THE INVENTION

### 1. Conventional Features of Plasma Chamber

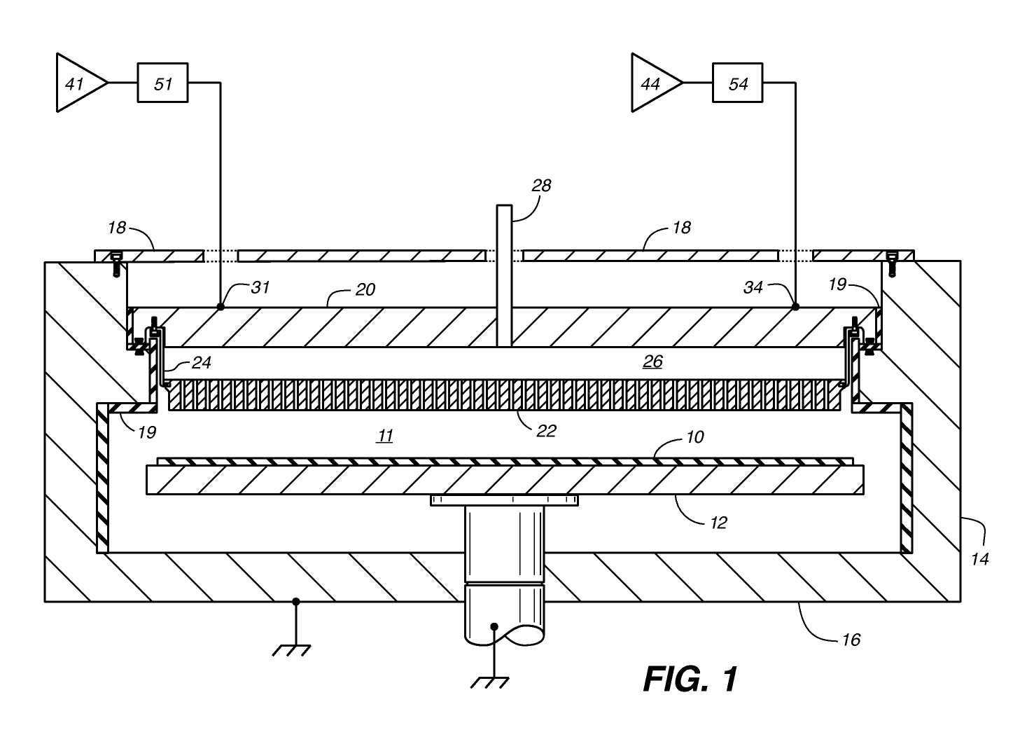

FIG. 1 shows a plasma chamber that is conventional except that it has multiple RF connection points 31-34 that receive power from respective RF power sources 41-44.

A workpiece 10 is supported on a susceptor 12 within the plasma chamber. The plasma chamber is intended to subject the workpiece to a plasma process step for fabricating on the workpiece electronic devices such as semiconductor devices, displays, solar cells, or solid state light emitting devices. Examples of a workpiece 10 that would be processed within the plasma chamber include a rectangular glass substrate on which flat panel displays are fabricated or a circular semiconductor wafer on which integrated circuits are fabricated.

The plasma chamber has an electrically conductive chamber wall 14-18, preferably aluminum, that provides a vacuum enclosure for the chamber interior. In the illustrated embodiment, the chamber side wall 14 and chamber bottom wall 16 are implemented as a unitary wall. The chamber wall also includes a chamber top wall 18. All portions of the chamber wall are connected together electrically and are electrically grounded.

In performing a plasma process on the workpiece 10, one or more process gases are dispensed into the chamber through a gas inlet manifold 20-24. The gas inlet manifold includes a manifold back wall 20, a showerhead 22 (also called a gas distribution plate or diffusor), and a suspension 24, all of which collectively enclose a volume which constitutes the interior 26 of the gas inlet manifold.

A gas inlet conduit 28 extends through the center of the manifold back wall 20. A gas source, not shown, supplies process gases to the upper end of the gas inlet conduit. The process gases flow from the gas inlet conduit into the interior 26 of the gas inlet manifold, and then are dispensed into the plasma chamber through numerous openings in the showerhead 22.

The weight of the showerhead is supported by the suspension 24, which is supported by the gas inlet manifold back wall 20, which is supported by the chamber side wall 14. The suspension 24 preferably is flexible so as to accommodate radial expansion and contraction of the showerhead as the temperature of the showerhead rises and falls. The suspension 24 has an upper end attached to the gas inlet manifold back wall 20 and a lower end attached to the rim at the periphery of the showerhead 22. The latter attachment can be either fixed or sliding. For example, a sliding attachment can be implemented by resting the showerhead rim on the lower end of the suspension.

If the showerhead is rectangular as in the illustrated embodiment, the vertically extending portion of the suspension 24 preferably consists of four flexible sheets respectively attached to the four sides of the rectangular showerhead 22. Each sheet extends vertically between one side of the rectangular showerhead and a corresponding side of the rectangular back wall 20.

The gas inlet manifold 20-24 also functions as an electrode of the plasma chamber because it functions to couple RF power to the plasma within the chamber. The manifold back wall 20, showerhead 22 and suspension 24 are electrically conductive, preferably aluminum. Dielectric liners 19 electrically and mechanically separate the RF powered components 20-24 of the gas inlet manifold from the electrically grounded chamber wall 14-18.

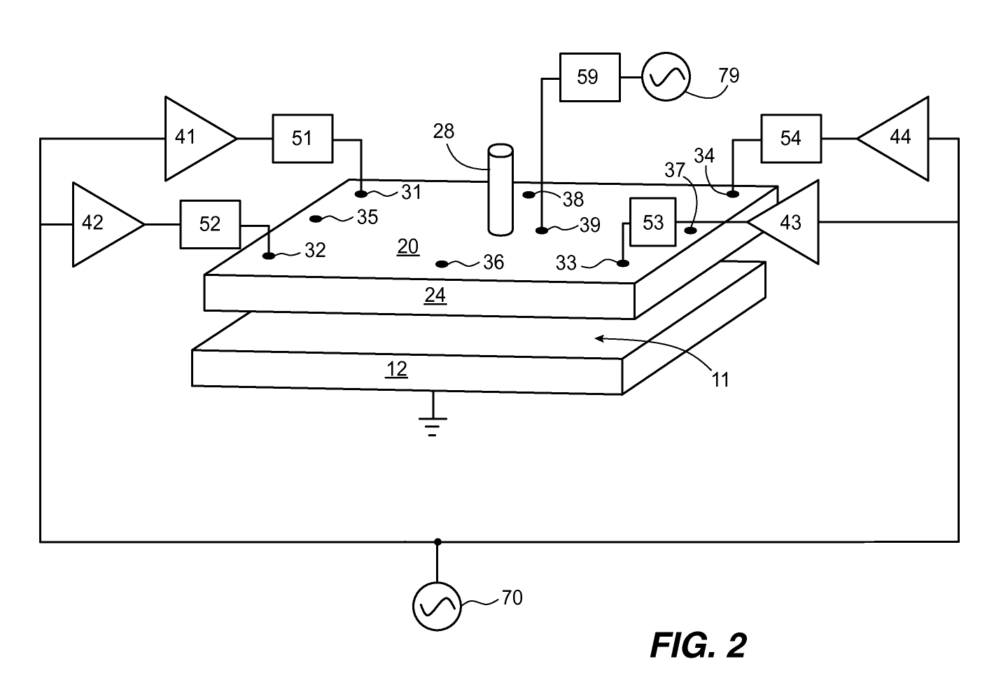

Referring to FIG. 2, the respective outputs of a plurality of RF power sources 41-44 are connected to respective RF connection points 31-34 on the rear surface of the manifold back wall 20. FIG. 2 illustrates these respective connections being made through respective impedance matching networks 51-54. The output of each respective RF power source 41-44 is coupled to the input of a respective RF impedance matching network 51-54. The output of each RF impedance matching network 51-54 is coupled to a respective RF connection point 31-34 on the electrode 20-24. Alternatively, the impedance matching networks can be omitted, and the respective RF power sources can be connected directly to the respective RF connection points.

(FIG. 2 shows all four RF power sources, matching networks, and RF connection points. FIG. 1 only shows two of each because FIG. 1 is a sectional view taken at a vertical plane that intersects the first two RF connection points 31, 32.)

We use the term “RF connection point” 31-34 to mean a position on an electrode 20-24 of the plasma chamber at which RF power is connected to the electrode.

Because the electrical function of the gas inlet manifold is more relevant to the present invention than its gas distribution function, we refer to it in the remainder of this patent specification as an electrode 20-24 of the plasma chamber rather than as the gas inlet manifold.

Although the electrode in the illustrated embodiment is a gas inlet manifold 20-24, the scope of invention includes RF connection points on any conventional plasma chamber electrode, regardless of whether the electrode has a gas distribution function. In other words, the electrode need not be part of a gas inlet manifold and need not include a showerhead.

Furthermore, the electrode can be outside the chamber wall 14-18 if it is adjacent to a portion of the chamber wall that is dielectric, thereby permitting RF power to be capacitively coupled from the electrode to the plasma within the chamber. Because the electrode can be inside or outside the chamber wall, the electrode is described herein as an electrode “of” the chamber rather than an electrode “in” the chamber.

RF power flows from the outputs of the respective RF power sources 41-44 to the respective RF connection points 31-34 on the manifold back wall 20, then along the manifold back wall to the four suspension walls 24 at the four sides of the manifold back wall, then along the four suspension walls to the four sides of the showerhead 22. The RF power is coupled from the showerhead to a plasma in the region 11 between the showerhead and the susceptor.

The term “RF” as used in this patent specification is not intended to limit the RF signals to any specific frequency range. By way of example but not limitation, the RF signals used in the invention can have a frequency in any of the ranges commonly referred to as LF, HF, VHF, UHF or microwave.

### 2. Time-Varying Phase Modulation

The invention is beneficial to improve the spatial uniformity of the plasma within a plasma chamber when an RF-powered electrode is sufficiently large relative to the wavelength of the RF power that the spatial distribution of the RF power on the electrode significantly affects the spatial distribution of the plasma within the plasma chamber. Accordingly, while the following is not a requirement of the invention, the invention is most useful when the largest dimension of the electrode 20-24 is greater than one-tenth of the wavelength of the RF power signal in the plasma. In other words, the invention is most useful when the first RF frequency is high enough relative to the size of the electrode such that the wavelength of the RF power signal in the plasma is shorter than ten times the largest dimension of the electrode.

When discussing the spatial distribution of the RF connection points 31-34 and the resulting RF voltages and plasma density, we refer the horizontal direction in FIG. 1 as the X-axis, the direction perpendicular to the page in FIG. 1 as the Y-axis, and the vertical direction in FIG. 1 as the Z-axis. In other words, the electrode 20-24 is approximately parallel to the X-Y plane, and the Z-axis extends approximately perpendicularly between the electrode 20-24 and the susceptor 12.

FIG. 2 shows an embodiment of the invention in which four RF power sources 41-44 respectively couple RF power to four RF connection points 31-34 that are positioned adjacent to the four corners of a rectangular electrode 20-24. More specifically, the RF connection points 31-34 are on the manifold back wall 20, respectively adjacent to its four corners.

The four RF connection points 31-34 are spatially distributed along both the X-axis and the Y-axis. More generally, the invention does not require the number of RF connection points to be four, but the invention does require the RF connection points to include at least three RF connection points that are not collinear. This assures that the RF connection points are distributed in at least two dimensions.

FIG. 2 also shows a second group of RF connection points 35-38 that are positioned adjacent to the centers of four sides of the rectangular electrode 20-24. More specifically, the second group of RF connection points 35-38 are on the manifold back wall 20, respectively adjacent to the centers of the four sides of its perimeter. As described below, the four RF power sources 41-44 can be connected to the second group of RF connection points 35-38 instead of the first four RF connection points 31-34. Alternatively, eight RF power sources can be provided to couple eight distinct RF power signals to the eight respective RF connection points 31-38.

More generally, there can be any integer number N of RF connection points 31-34 at locations spatially distributed in two dimensions (for example, along the X and Y axes) on the electrode 20-24, and an equal number N of RF power sources 41-44, wherein N is greater than or equal to three.

The electrode 20-24 need not be rectangular. For example, a circular electrode is useful for processing a circular workpiece 10 such as a semiconductor wafer. Any number N of RF connection points 31-38 can be spatially distributed in two dimensions over an electrode of any shape. For example, the RF connection points can be azimuthally distributed around the perimeter of a circular electrode. The RF connection points also can be radially distributed, i.e., located at different distances from the geometric center of the electrode.

A feature of the invention is that each RF power source 41-44 (excluding the additional RF power source 79 discussed below) outputs a respective RF power signal Vᵢ(t), for i=1 to N, having the same RF frequency f as a reference RF signal, and having a phase offset relative to said reference RF signal. We represent the respective phase offsets of the respective RF power signals by the symbol Φᵢ(t), for i=1 to N. Accordingly, the RF power signals are represented by the following equation:

Vᵢ(t)=sin {ft*360°−φᵢ(t)}, for i=1 to N.

The “reference RF signal” as used in this patent specification is a reference waveform having a predetermined frequency and phase relative to which the frequency and phase of each RF power signal Vᵢ(t) of the invention are established. We refer to the frequency of the reference RF signal as the reference RF frequency, represented by the symbol f. As explained below in the section “10. Hardware Implementation”, the reference RF signal does not need to be generated or to otherwise physically exist. Instead, the RF power sources 41-44 can produce RF power signals having phase offsets specified by the phase modulation functions φᵢ(t) described herein, using a conventional circuit such as a phase-locked loop or a direct digital synthesizer to derive the RF frequency and phase offsets from a reference clock signal or a reference oscillator signal produced by a reference oscillator 70. The reference clock signal or reference oscillator signal can have a frequency different from the reference RF signal.

Any frequency (represented by the symbol f or F) in this patent specification can be converted to the equivalent angular frequency (represented by the symbol Ω or ω) by dividing by 360°. For example, the expression (f*360°) can be replaced with Ω, and the expression (F*360°) can be replaced with ω. An asterisk symbol (*) represents the multiplication operator, and the caret symbol (̂) represents the exponentiation operator.

Applying a time-varying phase offset to a signal is conventionally referred to as phase modulation. Therefore, we use the term “phase modulation function” to refer to the aforesaid functions of time Φᵢ(t) that represent the phase offsets of the respective RF power signals relative to the reference RF signal.

An additional feature of the invention is that the respective phase modulation functions Φᵢ(t) are distinct functions of time. By “distinct” we mean that no two of the phase modulation functions are identical functions of time. In other words, no two of the phase modulation functions have the same values at all times. However, it is acceptable that two or more of the phase modulation functions have the same values at some points in time. Furthermore, a “function of time” is not required to be time-varying. One of the phase modulation functions can be a constant value or zero, for reasons that will be explained below.

In the notation used in this patent specification, successively numbered subscripts refer to the RF power sources 41-44 coupled to RF connection points 31-34 located at successive positions in either a clockwise or counterclockwise direction (in other words, successive azimuthal positions) on the electrode 20-24. We use the noun “azimuth” and the adjective “azimuthal” to mean the dimension orthogonal to the radial dimension in a 2-dimensional polar coordinate system. A positive or negative value of Φᵢ(t) represents a phase delay or a phase advance, respectively, in units of degrees.

At any instant in time, the phase differences among the output signals of the four RF power sources 41-44 produces an instantaneous spatial distribution of RF electric field and an instantaneous spatial distribution of plasma density in the region 11 between the electrode 20-24 and the susceptor 12 in the form of an interference pattern having instantaneous maxima and minima of RF electric field and instantaneous maxima and minima of plasma density at different locations along the X and Y axes.

Because the respective phase modulation functions Φ₁(t), Φ₂(t), Φ₃(t) and Φ₄(t) are distinct functions of time, the aforesaid instantaneous spatial distributions are time-varying. In other words, the instantaneous spatial distribution of RF electric field and the instantaneous spatial distribution of plasma density have maxima and minima at locations that shift spatially over time. Advantageously, the resulting spatial distribution of plasma in the plasma chamber generally has a better time-averaged uniformity than the uniformity of the spatial distribution at any instant in time.

The RF power sources 41-44 can output identical levels of RF power, but this is not required. The spatial uniformity of the plasma density or the spatial uniformity of one or more properties of a layer being fabricated on the workpiece 10 can be further optimized by establishing different respective levels of RF power output for the respective RF power sources 41-44.

### 3. Periodic Phase Modulation Functions

According to the first embodiment or first aspect of the invention summarized in the above “Summary of the Invention”, at least all but one of the phase modulation functions Φ₁(t) is a distinct, periodic function of time characterized by a repetition period. In other words, Φᵢ(t)=Φᵢ(t+1/Fᵢ) and, where (1/Fᵢ) is the repetition period of the i-th phase modulation function. We refer to Fᵢ as the “phase modulation repetition frequency” (or simply the “phase modulation frequency”) of the i-th phase modulation function Φᵢ(t).

The reason that one of the phase modulation functions is not required to be a periodic function of time is that the spatial distribution of the RF electric field produced by the RF power signals is a function of the phases of the RF power signals relative to each other. If one of the RF power signals has a constant or zero phase offset relative to the reference RF signal, each of the other RF power signals will still have a time-varying, periodic phase offset relative to said one RF power signal and relative to each other.

Advantageously, if at least all but one of the phase modulation functions (DM) is periodic as just described, the RF power respectively coupled to the plasma from each of the N RF power sources 41-44 will be superimposed to produce a plasma spatial distribution that varies with time with a repetition period less than or equal to the product of the repetition periods of the N phase modulation functions. If two or more of the repetition periods are equal or are in a ratio that is a rational number, the repetition period of the superposed spatial distribution will be the least common multiple (lowest common denominator) of the respective repetition periods of the N phase modulation functions.

The time-averaged spatial distribution of the plasma over this repetition period generally is more uniform than the spatial distribution of the plasma at any instant. Therefore, the time-averaged uniformity of the plasma process being performed on the workpiece is improved.

In one embodiment, each periodic phase modulation function Φᵢ(t) is a sinusoidal waveform having frequency Fᵢ, the most general expression of which is:

Φᵢ(t)=Aᵢ*sin(Fᵢt*360°−Δθᵢ), for i=1 to N.

A useful example of a periodic phase modulation function that is not sinusoidal is a sawtooth waveform that is a linear function of time. Two examples of sawtooth waveforms are Φᵢ(t)=Aᵢ*{(Fᵢt) modulo 1} and Φᵢ(t)=Aᵢ*{2*[(Fᵢ(t) modulo 1]−1}. The sawtooth waveform ranges between 0 and 1 in the first example and ranges between −1 and 1 in the second example.

Additional useful examples of a periodic phase modulation function are a triangle waveform and a trapezoidal waveform, the latter being a triangle waveform whose peaks are clipped above a predetermined magnitude so that the waveform has a flat top. An additional useful example is a Heaviside step function H(x), wherein H(x)=−1 if x<0 and H(x)=+1 if x>0.

In the equations of the two preceding paragraphs, each Aᵢ represents an amplitude parameter having units of degrees that determines the maximum phase offset of the RF power signal produced by the i-th RF power source 41-44 relative to the reference RF signal. Each Δθᵢ represents a phase offset constant. The respective values of each amplitude parameter Aᵢ and each phase offset constant Δθ₁ can be established empirically to optimize the time-averaged spatial uniformity of the plasma.

An important feature of the invention is the aforesaid amplitude parameter Aᵢ, which is the maximum phase offset applied to each of the RF power sources 41-44 relative to the reference RF signal. The maximum phase offset Aᵢ strongly affects the distribution of the interference pattern of the RF voltage and plasma density in the region between the electrode 20-24 and the susceptor 12. Specifically, the maximum phase offset Aᵢ determines the scale of the modulation of the interference pattern along the radial direction perpendicular to the Z-axis through the geometric center of the electrode. Larger values of Aᵢ increase the distance along such radial direction that the interference pattern is perturbed in response to the time-varying phase modulation. Therefore, the value of Aᵢ strongly affects the time-averaged uniformity of the RF voltage and plasma density along a radius extending from the center of the electrode toward the perimeter of the electrode.

The maximum phase offset Aᵢ preferably is established as a value determined empirically so as to maximize the spatial uniformity of the plasma density or the spatial uniformity of one or more properties of a layer being fabricated on the workpiece 10. For example, a fabrication process can be performed repeatedly in the plasma chamber, employing a different value of Aᵢ in each repetition, in order to observe which value of Aᵢ produces the best spatial uniformity of one or more properties of a layer being fabricated on the workpiece.

As indicated by the subscript “i”, the maximum phase offset Aᵢ can be established as a different value for each RF power source 41-44. Alternatively, the value of Aᵢ can be the same for each RF power source. In fact, we did use identical values of Aᵢ for each of the 40 MHz RF power sources 40-44 in the embodiments of the invention whose test results are described below under the heading “6. Test Results with Single Modulation Frequency and Two RF Power Frequencies”. When the value of Aᵢ is the same for each phase shifter, the term Aᵢ can be replaced by A in the equations describing the phase modulation functions Φᵢ(t).

### 4. Phase Modulation with Single Modulation Frequency

In one embodiment of the periodic phase modulation functions described in the preceding section, each phase modulation function Φᵢ(t) is periodic and has the same phase modulation repetition frequency F. In other words, Fᵢ=F for i=1 to N, so that Φᵢ(t)=Φᵢ(t+1/F).

Equivalently, we can express the aforesaid phase modulation functions Φᵢ(t) as the product of an amplitude parameter Aᵢ and a normalized phase modulation function Pᵢ(t), wherein each normalized phase modulation function has the same phase modulation repetition frequency F:

Φᵢ(t)=Aᵢ*Pᵢ(t), for i=1 to N.

Pᵢ(t)=Pᵢ(t+1/F), for i=1 to N.

By “normalized” we mean that each normalized phase modulation function Pᵢ(t) has a dimensionless value whose peak amplitude is normalized to 1 so that the value of Pᵢ(θ) ranges between −1 and +1. This definition of “normalized” includes the subset of embodiments in which Pᵢ(t) only has non-negative values, so that the value of Pᵢ(θ) ranges between 0 and 1.

Each amplitude parameter Aᵢ has units of degrees and determines the maximum phase offset of the RF power signal produced by the i-th RF power source 41-44 relative to the reference RF signal. The value of each parameter Aᵢ can be established empirically to optimize the time-averaged spatial uniformity of the plasma.

In one embodiment, each normalized phase modulation function Pᵢ(t) is a sinusoidal waveform having the same frequency F, the most general expression of which is as follows, wherein each Δθᵢ represents a phase offset constant as described above:

Pᵢ(t)=sin(Ft*360°−Δθᵢ), for i=1 to N.

In this embodiment, the respective phase modulation functions Φᵢ(t) are defined by the following equation:

Φᵢ(t)=Aᵢ*sin(Ft*360°−Δθᵢ), for i=1 to N.

Preferably, the phase offset constants Δθᵢ are established such that the plasma spatial distribution created by the superposition of the RF power from each of the RF power sources rotates progressively clockwise or counterclockwise. This is achieved if the respective phase offset constants Δθᵢ of the respective RF power sources 41-44 connected to successively positioned RF connection points 31-34 have monotonically increasing values. In other words, Δθᵢ₊₁>Δθᵢ, for i=1 to (N-1). By “successively positioned” we mean located at successive positions in either a clockwise or counterclockwise direction (in other words, successive azimuthal positions) on the electrode 20-24.

The rotation described in the preceding paragraph can be applied to the preferred embodiment of the invention illustrated in FIG. 2 in which the electrode 20-24 is rectangular and there are four RF connection points 31-34 respectively adjacent four corners of the electrode. Alternatively, the four RF connection points may be adjacent to the respective centers of the four respective sides of the rectangular electrode as illustrated by the alternative four RF connection points 35-38 in FIG. 2.

When the number of RF connection points 31-34 and the number of RF power sources 41-44 is four, the respective normalized phase modulation functions Pᵢ(t) of the RF power supplied to the four respective RF connection points 31-34 at successive positions clockwise or counterclockwise around the electrode preferably differ by 90° increments, such that Δθᵢ=i*90°. Consequently, the normalized phase modulation functions are 90° out of phase for each pair of successive (i.e., adjacent) RF connection points, and are 180° out of phase for each pair of opposite RF connection points (31, 33) or (32, 34). This is expressed in the following equations:

Pᵢ(t)=sin(Ft*360°−i*90°, for i=1, 2, 3 & 4.

Φᵢ(t)=Aᵢ*Pᵢ(t)=Aᵢ*sin(Ft*360°−i*90°, for i=1, 2, 3 & 4.

Alternatively, as stated above in the section “2. Time-Varying Phase Modulation”, the electrode 20-24 need not be rectangular. For example, a circular electrode is useful for processing a circular workpiece 10 such as a semiconductor wafer. Any number N of RF connection points 31-34 can be spatially distributed in two dimensions over such electrode, such as by being azimuthally distributed around the perimeter of a circular electrode. Preferably the respective normalized phase modulation functions Pᵢ(t) of the RF power supplied to the N respective RF connection points 31-34 at successive positions clockwise or counterclockwise around the electrode differ by equal increments, such that Δθᵢ=i*360°/N for i=1 to N. This is expressed in the following equations:

Pᵢ(t)=sin(Ft*360°−i*360°/N), for i=1 to N.

Φᵢ(t)=Aᵢ*Pᵢ(t)=Aᵢ*sin(Ft*360°−i*360°/N), for i=1 to N.

### 5. Additional RF Power Source at Lower Frequency

The second embodiment or second aspect of the invention summarized in the above “Summary of the Invention” includes an additional RF power source 79 that outputs an RF power signal having a second RF frequency that is lower than the reference RF frequency f. A lower frequency RF power signal generally produces an electric field spatial distribution having more widely spaced instantaneous peaks and minimums in comparison with a higher frequency RF power signal. Therefore, by coupling lower frequency RF power to the plasma, the additional RF power source can increase the plasma density at one or more locations of instantaneous or time-averaged minimums in the interference pattern produced by the multiple RF power sources 41-44 at the higher first frequency. In the absence of such lower frequency additional RF power source 79, we found that instantaneous minimums could possibly make the plasma less uniform, depending on the operating conditions of the plasma chamber.

The output of the additional RF power source 79 is coupled through an RF impedance matching network 59 to one or more RF connection points 39 on the electrode 20-24. A single RF connection point 39 at or near the center of the electrode typically suffices. Alternatively, the additional RF power source 79 can be coupled to one of the RF connection points 31-34 that is connected to one of the higher frequency RF power sources 41-44.

### 6. Test Results with Single Modulation Frequency and Two RF Power Frequencies

Applicant successfully tested the invention in a plasma chemical vapor deposition chamber designed for a rectangular workpiece 10 of size 2.2 by 2.6 meters. The configuration of the electrode 20-24 and the arrangement of RF connection points 31-34, 39 was as shown in FIGS. 1 and 2. Specifically, four RF connection points 31-34 adjacent to the four corners of the manifold back wall 20 were connected to receive RF power from four RF power sources 41-44 at a first RF frequency of 40.86 MHz. A fifth RF connection point 39 near the center of the manifold back wall was connected to receive RF power from an additional RF power source 79 at a lower RF frequency of 13.56 MHz. The size of the susceptor 12 was 2.4 by 2.75 meters, and the showerhead 22 was slightly larger.

The wavelength in vacuum of 40.86 MHz is 7.34 meters, which is less than three times the longest dimension of the electrode 20-24. The wavelength of 40 MHz in the plasma is even shorter, depending on plasma conditions such as chemical composition, plasma density, and chamber pressure. Therefore the 40 MHz RF power sources 40-44 would produce a badly non-uniform standing wave pattern in the plasma in the absence of time-varying phase modulation according to the invention.

We tested the invention with a process for depositing a silicon film on the workpiece using silane gas mixed with hydrogen gas as a reagent. We measured the non-uniformity of the deposition rate of the silicon film along a diagonal between two opposite corners of the workpiece. The results are summarized in Table 1. In all tests listed in Table 1, the power level of the 13 MHz RF power source was 10 kW, and the temperature of the susceptor 12 was 180° C. The hydrogen gas flow rate was 100×10³ sccm in all tests in Table 1 except for the third test (whose deposition rate was 635 Å/min) in which it was 140×10³ sccm. The electrode gap listed in Table 1 is the spacing between the susceptor 12 and the showerhead 22. In the column “40 MHz Power”, the expression “4×10” means that 10 kW of power was supplied by each of the four 40 MHz power sources 41-44.

The phase modulation function for the four 40 MHz RF power sources 41-44 was sinusoidal with a phase modulation repetition frequency F of 1 KHz. The maximum amplitude A of the phase modulation was the same for each of the four RF power sources 41-44. In other words, Aᵢ=A for i=1 to 4. Values of A equal to 54°, 72° and 90° were tested, as shown in Table 1. We found that increasing the value of A moved the regions of maximum average deposition rate closer to the corners of the rectangular workpiece, and decreasing the value of A moved these regions closer to the center. The value of A that maximized average spatial uniformity of deposition rate depended on other process conditions, as summarized in Table 1.

TABLE 1

| | SiH₄ | | | | | |
|---|---|---|---|---|---|---|
| | Flow | | | | Depo- | |
| Chamber | Rate | Electrode | | | sition | Non- |
| Pressure | (sccm × | Gap | 40 MHz | | Rate | Uni- |
| (Torr) | 10³) | (inch) | Power (kW) | A | (Å/min) | formity |
| 4 | 4 | .75 | 4 × 10 | 72° | 558 | 42% |
| 4 | 4 | .675 | 4 × 10 | 72° | 700 | 46% |
| 4 | 4 | .675 | 4 × 10 | 72° | 635 | 53% |
| 4 | 4 | .675 | 4 × 12.5 | 72° | 664 | 51% |
| 3.5 | 4 | .675 | 4 × 10 | 72° | 743 | 55% |
| 4 | 2.5 | .75 | 4 × 10 | 90° | 370 | 26% |
| 4 | 3.5 | .675 | 4 × 12.5 | 72° | 608 | 48% |
| 4 | 3.5 | .675 | 4 × 12.5 | 54° | 618 | 49% |
| 4 | 4 | .75 | 4 × 12.5 | 72° | 607 | 27% |
| 4 | 2.5 | .75 | 4 × 6 | 90° | 422 | 39% |
| 4 | 2.5 | .75 | 4 × 10 | 90° | 408 | 68% |
| 4 | 2.5 | .75 | 4 × 10 | 72° | 390 | 36% |
| 4 | 4 | .75 | 4 × 10 | 72° | 616 | 33% |
| 4 | 5 | .75 | 4 × 10 | 72° | 726 | 40% |
| 4 | 5 | .75 | 4 × 12.5 | 72° | 712 | 40% |
| 3 | 5 | .75 | 4 × 12.5 | 72° | 856 | 46% |

### 7. Radial & Azimuthal Sweep with 2 Phase Modulation Frequencies at Successive Points

In additional embodiments of the invention, two different phase modulation repetition frequencies F₁ and F₂ can be used simultaneously to produce a time-varying electric field pattern that combines a rotational (i.e., azimuthal) sweep as in the previously described single modulation frequency embodiments and a radial sweep. Advantageously, because the electric field pattern sweeps in two orthogonal dimensions (radial and azimuthal), the spatial distribution of the plasma in the plasma chamber can achieve better time-averaged uniformity than typically could be achieved by sweeping in only one dimension.

One such embodiment includes four RF connection points 31-34 at successive positions in either a clockwise or counterclockwise direction (in other words, successive azimuthal positions) on the electrode 20-24. For example, the four RF connection points 31-34 can be adjacent four corners of the rectangular electrode as in the embodiment of FIG. 2, or alternatively they can be adjacent to the respective centers of four sides of the rectangular electrode as illustrated by the four RF connection points 35-38 in FIG. 2. Preferably the four RF connection points are equally spaced azimuthally; in other words, preferably they are spaced 90° apart in azimuth, as is true of either the first four RF connection points 31-34 or the alternative four RF connection points 35-38.

As in all the previously discussed embodiments, each of the four RF power sources 41-44 outputs an RF signal having the same RF frequency f as the reference RF signal. The respective outputs Vᵢ(t) of the four RF power sources 41-44 have respective phase offsets Φᵢ(t) relative to the reference RF signal specified by the following phase modulation functions Φᵢ(t), wherein the two phase modulation repetition frequencies F₁ and F₂ are not equal:

Vᵢ(t)=sin {ft*360°−Φᵢ(t)}, for i=1, 2, 3 & 4.

Φ₁(t)=A₁ sin(F₁t*360°

Φ₂(t)=A₂ sin(F₂t*360°

Φ₃(t)=−Φ₁(t)

Φ₄(t)=−Φ₂(t)

The time-varying instantaneous electric field pattern can be understood by first considering the contributions from only the odd-numbered or only the even-numbered RF connection points. First, consider only the RF power V₁(t) and V₃(t) respectively supplied by the first and third RF power sources 41, 43 to the first and third RF connection points 31, 33:

V₁(t)=sin {ft*360°−A₁ sin(F₁t*360°)}

V₃(t)=sin {ft*360°+A₁ sin(F₁t*360°)}

Because the first and third RF connection points 31, 33 are diagonally opposite and are shifted in phase in opposite directions, their combined time-varying electric field pattern will have instantaneous peaks and minimums that shift back and forth along the diagonal between the first and third RF connection points at a repetition frequency equal to the first phase modulation repetition frequency F₁.

Similarly, consider only the RF power V₂(t) and V₄(t) respectively supplied supplied by the second and fourth RF power sources 42, 44 to the second and fourth RF connection points 32, 34. Their combined time-varying electric field pattern will have instantaneous peaks and minimums that shift back and forth along the diagonal between the second and fourth RF connection points at a repetition frequency equal to the second phase modulation repetition frequency F₂.

V₂(t)=sin {ft*360°−A₂ sin(F₂t*360°)}

V₄(t)=sin {ft*360°+A₂ sin(F₂t*360°)}

Now consider the combined electric field all four RF power signals V₁(t) through V₄(t). Because the two time-varying electric field patterns just described are shifting in approximately orthogonal directions at different rates F₁ and F₂, their combined electric field pattern rotates about the geometric center of the four RF connection points.

The rotation described in the preceding paragraph causes the instantaneous peaks and minimums to sweep across the full 360° azimuth of the electrode. The diagonal shifting of the instantaneous peaks and minimums described in the earlier paragraphs of this section causes the instantaneous peaks and minimums to sweep radially; in other words, to sweep back-and-forth between the center and the perimeter of the electrode. Therefore, the invention sweeps the electrical field in two orthogonal dimensions: radial and azimuthal.

Advantageously, this combination of azimuthal and radial sweeping of the instantaneous spatial pattern of the electric field can achieve a spatial distribution of the plasma in the plasma chamber having better time-averaged uniformity than typically could be achieved by sweeping in only one dimension.

Although not required, the two phase modulation repetition frequencies typically will be approximately the same order of magnitude, such as 1000 Hz and 1100 Hz, respectively.

The values of the two maximum phase offset parameters A₁ and A₂ can be the same, or they can be different to compensate for any asymmetry in the electrode or the plasma chamber. For example, if the electrode is rectangular, and if the first and third RF connection points 31, 33 are more widely spaced than the second and fourth connection points 32, 34, then establishing a greater value for A₁ than A₂ may improve spatial uniformity.

Although not required, we expect values of A₁ and A₂ in the range of 30° to 90° to be preferred. Values of A₁ and A₂ that optimize uniformity of the electric field, the plasma density, or a characteristic of the plasma process being performed on the workpiece can be determined empirically.

Alternatively, the parameters A₁ and A₂ can be replaced with a periodic function having a repetition frequency that is lower than F₁ and F₂:

Φ₁(t)=A(t)*sin(F₁t*360°)

Φ₂(t)=A(t)*)sin(F₂t*360°)

Φ₃(t)=−Φ₁(t)

Φ₄(t)=−Φ₂(t)

A first example of A(t) as a periodic function is:

A(t)=B₁+(B₂−B₁){sin(F₃t*360°)}̂2

A second example of A(t) as a periodic function is:

A(t)=B₁+(B₂−B₁){1 +cos(F₃t*360°)}/2

In both preceding examples, F₁>F₂>F₃, and B₁ and B₂ are parameters that can be established to optimize spatial uniformity.

Instead of two sinusoidal phase modulation functions, the embodiment of the invention presented at the beginning of this section can be generalized in terms of two phase modulation functions Φ₁(t) and Φ₂(t) that need not be sinusoidal and that are periodic with distinct phase modulation repetition frequencies F₁ and F₂, respectively:

Vᵢ(t)=sin {ft*360°−Φᵢ(t)}, for i=1, 2, 3 & 4.

Φ₃(t)=−Φ₁(t)

Φ₄(t)=−Φ₂(t)

A further variation on the embodiment expressed in the preceding paragraph is for the each of the first two phase modulation functions to be the sum of a sinusoidal function and a Heaviside step function H(x), wherein A and B are parameters, having units of degrees, whose values can be established empirically to optimize spatial uniformity of the plasma process:

Φ₁(t)=A sin(F₁t*360°)+B*H{sin(F₃t*360°)}

Φ₂(t)=A sin(F₂t*360°)+B*H{sin(F₃t*360°)}

Φ₃(t)=−Φ₁(t)

Φ₄(t)=−Φ₂(t)

wherein F₁>F₂>F₃; and
wherein H(x)=−1 if x<0 and H(x)=+1 if x>0.

The repetition period of the instantaneous spatial distribution produced by the preceding embodiment will be the least common multiple (lowest common denominator) of F₁, F₂, and F₃. For given values of F₁ and F₂, the repetition period will be shortest if F₃ is the greatest common divisor of F₁ and F₂.

### 8. Sweep in X and Y Dimensions with Two Phase Modulation Frequencies

In another embodiment of the invention, two different phase modulation repetition frequencies F₁ and F₂ can be used simultaneously to produce a time-varying electric field pattern that combines a sweep at a first phase modulation repetition frequency F₁ along a first linear axis and a sweep at a second phase modulation repetition frequency F₂ along a second linear axis that is orthogonal to the first axis. Advantageously, because the electric field pattern sweeps in two orthogonal dimensions, the spatial distribution of the plasma in the plasma chamber can achieve better time-averaged uniformity than typically could be achieved by sweeping in only one dimension.

This embodiment of the invention includes four RF connection points 31-34 at successive positions in either a clockwise or counterclockwise direction (in other words, successive azimuthal positions) on the electrode 20-24. For example, the four RF connection points 31-34 can be adjacent four corners of the electrode as in the embodiment of FIG. 2, or they can be adjacent to the respective centers of four sides of the electrode as illustrated by the alternative four RF connection points 35-38 in FIG. 2.

As in all the previously discussed embodiments, each of the four RF power sources 41-44 outputs an RF signal having the same RF frequency f as the reference RF signal. The respective outputs Vᵢ(t) of the four RF power sources 41-44 have respective phase offsets Φᵢ(t) relative to the reference RF signal specified by the following phase modulation functions Φᵢ(t), wherein the two phase modulation repetition frequencies F₁ and F₂ are not equal:

Vᵢ(t)=sin {ft*360°−Φᵢ(t)}, for i=1, 2, 3 & 4.

Φ₁(t)=A₁ sin(F₁t*360°)

Φ₂(t)=−₁(t)

Φ₃(t)=Φ₂(t)+A₂ sin(F₂t*360°)

Φ₄(t)=Φ₁(t)+A₂ sin(F₂t*360°)

An equivalent alternative expression for this phase modulation scheme is:

Φ₁(t)=A₁ sin(F₁t*360°)−A₃ sin(F₂t*360°)

Φ₂(t)=−A₁ sin(F₁t*360°)−A₃ sin(F₂t*360°)

Φ₃(t)=−A₁ sin(F₁t*360°)+A₃ sin(F₂t*360°)

Φ₄(t)=A₁ sin(F₁t*360°)+A₃ sin(F₂t*360°)

wherein A₃=A₂/2.

Although not required, preferably the four RF connection points are positioned geometrically as the four vertices of a right rectangle. In that case, the aforesaid first axis (which we refer to as the 1-2 axis and the 3-4 axis) is both parallel to a geometric line extending between the first and second RF connection points 31,32 and is parallel to a geometric line extending between the third and fourth RF connection points 33,34. Similarly, the aforesaid second axis (which we refer to as the 2-3 axis) is both parallel to a geometric line extending between the second and third RF connection points 32,33 and is parallel to a geometric line extending between the first and fourth RF connection points 31,34.

Because the components of Φ₁(t) and Φ₂(t) having frequency F₁ are opposite in phase, and because the components of Φ₃(t) and Φ₄(t) having frequency F₁ are opposite in phase, the resulting electric field sweeps back and forth along the first axis (the 1-2 axis and the 3-4 axis) at the first phase modulation repetition frequency F₁.

Because the components of Φ₂(t) and Φ₃(t) having frequency F₂ are opposite in phase, and because the components of Φ₁(t) and Φ₄(t) having frequency F₂ are opposite in phase, the resulting electric field sweeps back and forth along the second axis (the 2-3 axis and the 1-4 axis) at the second phase modulation repetition frequency F₂.

Advantageously, because the electric field pattern sweeps in two orthogonal dimensions, the spatial distribution of the plasma in the plasma chamber can achieve better time-averaged uniformity than typically could be achieved by sweeping in only one dimension.

Although not required, the two phase modulation repetition frequencies can differ by an order of magnitude, such as F₁=1000 Hz and F₂=100 Hz, respectively, so that the electric field pattern sweeps ten times faster in one dimension than in the orthogonal dimension.

The values of the two maximum phase offset parameters A₁ and A₂ can be the same, or they can be different to compensate for any asymmetry in the electrode or the plasma chamber. For example, if the electrode is rectangular, and if the first and second RF connection points 31, 32 are more widely spaced than the second and third connection points 32, 33, then establishing a greater value for A₁ than A₂ may improve spatial uniformity.

Although not required, we expect values of A₁ and A₂ in the range of 30° to 90° to be preferred. Values of A₁ and A₂ that optimize uniformity of the electric field, the plasma density, or a characteristic of the plasma process being performed on the workpiece can be determined empirically.

### 9. Radial & Azimuthal Sweep with Product of Two Periodic Functions

In additional embodiments of the invention, two different phase modulation repetition frequencies F₁ and F₂ can be used simultaneously to produce a time-varying electric field pattern that combines a rotational (i.e., azimuthal) sweep as in the previously described single modulation frequency embodiments and a radial sweep. Advantageously, because the electric field pattern sweeps in two orthogonal dimensions (radial and azimuthal), the spatial distribution of the plasma in the plasma chamber can achieve better time-averaged uniformity than typically could be achieved by sweeping in only one dimension.

In one such embodiment, each phase modulation function Φᵢ(t) is the product of two periodic functions of time, Pᵢ(t) and Qᵢ(t), wherein each periodic function Pᵢ(t) has a first repetition frequency F₁, and each periodic function Qᵢ(t) has a second repetition frequency F₂ that is less than F₁:

Φᵢ(t)=Pᵢ(t)*Qᵢ(t)

Because its repetition frequency is lower, the periodic function Qᵢ(t) typically will produce an electric field distribution that sweeps radially inward and outward relative to the geometric center of the RF connection points while the periodic function Pᵢ(t) causes such electric field distribution to sweep azimuthally.

For example, such combination of radial and azimuthal sweeping can be achieved if the periodic function Pᵢ(t) is one of the alternatives described in the above section “4. Phase Modulation with Single Modulation Frequency”, such as:

Pᵢ(t)=sin(Ft*360°−Δθᵢ), for 1=1 to N.

### 10. Hardware Implementation

All of the embodiments of the invention described above include a plurality of RF power sources 41-44, each of which produces an RF power signal having a phase offset relative to a reference RF signal, wherein the phase offset is defined by a phase modulation function. Alternative phase modulation functions are defined above in connection with various alternative embodiments.

The RF power sources 41-44 of the invention are not limited to any specific hardware design for producing such RF power signals. By way of example but not limitation, the RF power sources can include a conventional circuit such as a phase shifter, a phase-locked loop or a direct digital synthesizer to derive the RF frequency and phase offsets Φᵢ(t) from a reference clock signal or a reference oscillator signal produced by a reference oscillator 70. Furthermore, the reference clock signal or reference oscillator signal can have a frequency different from the reference RF signal.

Various hardware designs for phase modulating an RF power signal are commonly available. The present invention is not intended to be limited to any specific hardware for implementing a phase modulation function or for phase modulating an RF power signal.

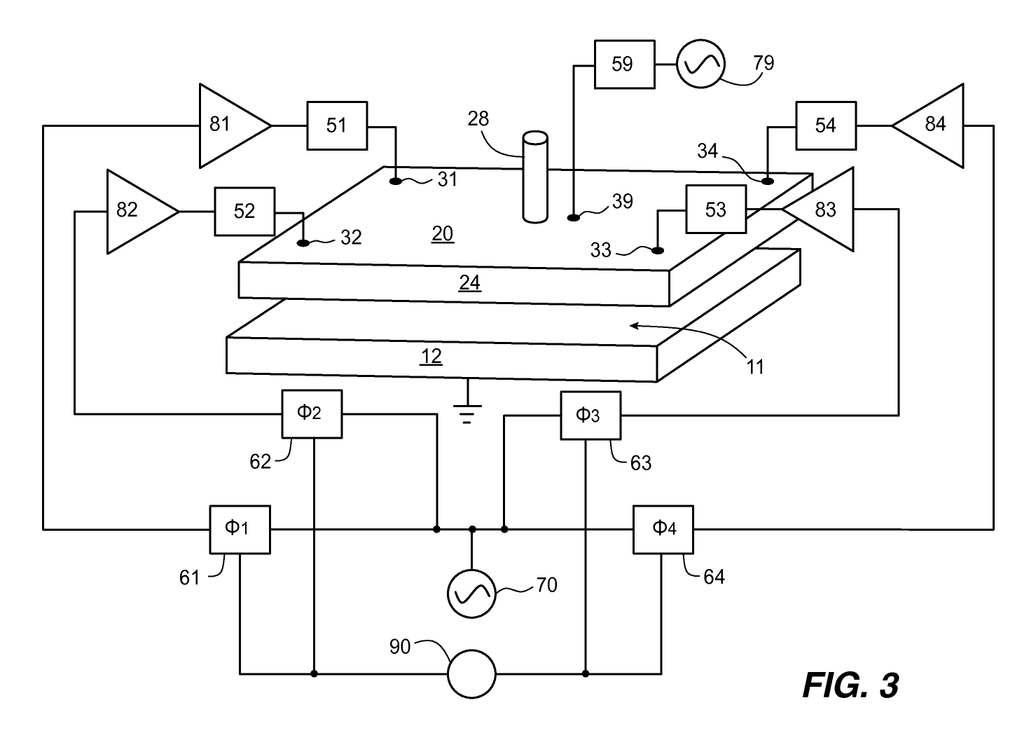

By way of example but not limitation, FIG. 3 illustrates a suitable hardware design. The RF power generators 81-84, phase shifters 61-64, and waveform generator 90 collectively implement the functionality of the RF power sources 41-44. Each RF power generator 81-84 has a sync input and an output. Each RF power generator produces at its output an RF power signal whose frequency and phase are synchronized to the frequency and phase of a sync signal received at the sync input. Although the sync signal can be a sinusoidal RF signal, more typically it is a digital logic signal having a pulse or square wave waveform.

A reference oscillator 70 produces a periodic reference clock signal or reference oscillator signal having either the same frequency f as the reference RF signal, or else a frequency from which the reference frequency f can be derived, typically by multiplication, division, or both. The reference clock signal or reference oscillator signal is coupled to each of a plurality of phase shifters 61-64.

Each respective phase shifter 61-64 also is connected to receive a phase modulation signal, produced by a waveform generator 90, that represents the respective phase modulation function Φᵢ(t). A conventional phase shifter circuit, such as a phase-locked loop circuit, can produce an output signal that is synchronized in phase with the reference RF signal (derived by the phase shifter from the signal received from the reference oscillator 70) and that is offset in phase from the reference RF signal by the phase offset specified by the phase modulation signal Φᵢ(t) received from the waveform generator 90. The output signal of each phase shifter is coupled to the sync input of each RF power generator 81-84.

In embodiments in which the phase modulation functions are sinusoidal and have the same phase modulation repetition frequency F, the waveform generator 90 can be a sinusoidal oscillator at frequency F. If the phase modulation functions are non-sinusoidal, the waveform generator can be a conventional function generator that is digitally programmable to synthesize any desired phase modulation functions. In particular, the waveform generator can be programmable to implement any of the parameters of the phase modulation functions described above, such as Fᵢ, Aᵢ(t) and Δθᵢ.

All the functions illustrated in FIG. 3 as separate phase shifters 61-64, reference oscillator 70, and waveform generator 90 can be combined in a commonly available integrated circuit or programmable computer. Furthermore, such a programmable computer can permit a user to modify any of the parameters of the phase modulation functions or the RF power sources.

1. Apparatus for coupling RF power to a plasma chamber comprising:
a plasma chamber electrode having first, second and third RF connection points that are not collinear; and
first, second and third RF power sources, wherein each respective RF power source includes an output at which it produces a first, second and third RF power signal, respectively;
wherein:
the respective outputs of the first, second and third RF power source are coupled to the first, second and third RF connection point, respectively;
each of the RF power signals has the same RF frequency;
the first and second RF power signals have a first phase offset and a second phase offset, respectively, relative to the third RF power signal; and
the first and second phase offsets are distinct, periodic functions of time characterized by a first repetition frequency and a second repetition frequency, respectively.

2. The apparatus of claim 1, wherein the first and second repetition frequencies are equal.

3. Apparatus for coupling RF power to a plasma chamber comprising:
a plasma chamber electrode; and
a number N of RF power sources, each RF power source having an output at which it produces a respective RF power signal, the number N being an integer greater than or equal to three;
wherein:
the output of each RF power source is coupled to a distinct RF connection point on the plasma chamber electrode;
said RF connection points include at least three RF connection points that are not collinear;
the frequency of each of the RF power signals equals the frequency of a reference RF signal;
the first through N-th RF power signals have a first through N-th phase offset, respectively, relative to the reference RF signal;
each of the phase offsets is a distinct function of time; and
at least (N−1) of the phase offsets are periodic functions of time.

4. The apparatus of claim 3, wherein one of the phase offsets is zero.

5. The apparatus of claim 3, wherein each of the phase offsets Φᵢ(t) is a time-varying function of a single phase modulation repetition frequency F such that:
Φᵢ(t)=Aᵢ*sin(Ft*360°−Δθᵢ), for i=1 to N;
wherein Aᵢ and Δθᵢ are predetermined values.

6. The apparatus of claim 5, wherein:
the respective RF connection points to which the respective outputs of the first through N-th RF power sources are coupled are located at successive positions on the plasma chamber electrode; and
Δθᵢ₊₁>Δθᵢ, for i=1 to (N−1).

7. The apparatus of claim 5, wherein:
the respective RF connection points to which the respective outputs of the first through N-th RF power sources are coupled are located at successive positions on the plasma chamber electrode; and
Δθᵢ=i*360°/N for i=1 to N.

8. The apparatus of claim 3, wherein:
the number of RF power sources and the number of RF connection points is four;
the respective RF connection points that are coupled to the respective outputs of the first, second, third and fourth RF power sources are located at successive positions on the plasma chamber electrode; and
each of the phase offsets Φᵢ(t) is a time-varying function of a single phase modulation repetition frequency F such that:
Φᵢ(t)=Aᵢ*sin(Ft*360°−i*90°), for i=1, 2, 3 and 4; and
Aᵢ are predetermined values for i=1, 2, 3 and 4.

9. The apparatus of claim 8, wherein:
the plasma chamber electrode is rectangular; and
the four RF connection points are positioned adjacent four respective corners of the plasma chamber electrode.

10. The apparatus of claim 8, wherein:
the plasma chamber electrode has a rectangular perimeter with four sides; and
the four RF connection points are positioned adjacent to the respective centers of the four respective sides of the perimeter of the plasma chamber electrode.

11. The apparatus of claim 3, wherein each of the phase offsets Φᵢ(t) is a time-varying function of first and second repetition frequencies F₁ and F₂ such that:
Φᵢ(t)=Aᵢ(t)*sin(F₁t*360°−Δθᵢ), for i=1 to N;
wherein Δθᵢ are predetermined values for i=1 to N; and
wherein, for i=1 to N, each Aᵢ(t) is a periodic function having a repetition frequency equal to F₂.

12. The apparatus of claim 3, wherein:
the number of RF power sources and the number of RF connection points is four;
the respective RF connection points that are coupled to the respective outputs of the first, second, third and fourth RF power sources are located at successive positions on the plasma chamber electrode; and
each of the phase offsets Φᵢ(t), for i=1, 2, 3 and 4, is a time-varying function of first and second distinct phase modulation repetition frequencies F₁ and F₂ such that:
Φ₁(t)=A₁ sin(F₁t*360°)
Φ₂(t)=A₂ sin(F₂t*360°)
Φ₃(t)=−Φ₁(t)
Φ₄(t)=−Φ₂(t)

13. The apparatus of claim 3, wherein:
the number of RF power sources and the number of RF connection points is four;
the respective RF connection points that are coupled to the respective outputs of the first, second, third and fourth RF power sources are located at successive positions on the plasma chamber electrode;
the phase offset of the first RF power source relative to the reference RF signal is a periodic function of time having a first repetition frequency;
the phase offset of the second RF power source relative to the reference RF signal is a periodic function of time having a second repetition frequency different from the first repetition frequency;
the phase offset of the third RF power source relative to the reference RF signal is minus one times the phase offset of the first power source; and
the phase offset of the fourth RF power source relative to the reference RF signal is minus one times the phase offset of the second power source.

14. The apparatus of claim 3, wherein:
the number of RF power sources and the number of RF connection points is four;
the respective RF connection points that are coupled to the respective outputs of the first, second, third and fourth RF power sources are located at successive positions on the plasma chamber electrode; and
each of the phase offsets Φᵢ(t), for i=1, 2, 3 and 4, is a time-varying function of first and second distinct frequencies F₁ and F₂ and of first and second predetermined parameters A₁ and A₂ such that:
Φ₁(t)=A₁ sin(F₁t*360°)
Φ₂(t)=−Φ₁(t)
Φ₃(t)=Φ₂(t)+A₂ sin(F₂t*360°)
Φ₄(t)=Φ₁(t)+A₂ sin(F₂t*360°)

15. The apparatus of claim 3, further comprising:
an additional RF power source having an output at which it produces an additional RF power signal having an RF frequency lower than the frequency of said reference RF signal;
wherein the output of the additional RF power source is coupled to the plasma chamber electrode.

16. The apparatus of claim 3, further comprising:
a reference oscillator that produces said reference RF signal;
wherein the reference oscillator is connected to provide the reference RF signal to each RF power source.

17. The apparatus of claim 3, further comprising:
a reference oscillator that produces a reference oscillator signal having a frequency different from said reference RF signal;
wherein the reference oscillator is connected to provide the reference oscillator signal to each RF power source; and
wherein each RF power source derives its respective RF power signal from the reference oscillator signal.

18. Apparatus for coupling RF power to a plasma chamber comprising:
a plasma chamber electrode having first, second and third RF connection points that are not collinear;
first, second and third RF power sources, wherein each respective RF power source includes an output at which it produces a first, second and third RF power signal, respectively, wherein each of the RF power signals has an RF frequency equal to a first frequency; and
an additional RF power source having an output at which it produces an additional RF power signal having an RF frequency lower than said first frequency;
wherein:
the respective outputs of the first, second and third RF power source are coupled to the first, second and third RF connection points, respectively;
the first and second RF power signals have a first phase offset and a second phase offset, respectively, relative to the third RF power signal, wherein the first phase offset and the second phase offset are distinct functions of time; and
the output of the additional RF power source is coupled to the plasma chamber electrode.

19. A method for coupling RF power to a plasma chamber comprising the steps of:
providing a plasma chamber electrode having first, second and third RF connection points that are not collinear; and
coupling a first, a second and a third RF power signal, respectively, to the first, second and third RF connection point, respectively;
wherein:
each of the RF power signals has the same RF frequency;
the first and second RF power signals have a first phase offset and a second phase offset, respectively, relative to the third RF power signal; and
the first and second phase offsets are distinct, periodic functions of time characterized by a first repetition frequency and a second repetition frequency, respectively.

20. The method of claim 19, wherein the first and second repetition frequencies are equal.

21. A method for coupling RF power to a plasma chamber comprising the steps of:
providing a plasma chamber electrode;
producing a number N of RF power signals, the number N being an integer greater than or equal to three; and
coupling each RF power signal to a distinct RF connection point on the plasma chamber electrode;
wherein:
said RF connection points include at least three RF connection points that are not collinear;
the frequency of each of the RF power signals equals the frequency of a reference RF signal;
the first through N-th RF power signals have a first through N-th phase offset, respectively, relative to the reference RF signal;
each of the phase offsets is a distinct function of time; and
at least (N−1) of the phase offsets are periodic functions of time.

22. The method of claim 21, wherein one of the phase offsets is zero.

23. The method of claim 21, wherein each of the phase offsets Φᵢ(t) is a time-varying function of a single phase modulation repetition frequency F such that:
Φᵢ(t)=Aᵢ*sin(Ft*360°−Δθᵢ), for i=1 to N;
wherein Aᵢ and Δθᵢ are predetermined values.

24. The method of claim 23, wherein:
the respective RF connection points to which the first through N-th RF power signals are coupled are located at successive positions on the plasma chamber electrode; and
Δθᵢ₊₁>Δθᵢ, for i=1 to (N−1).

25. The method of claim 23, wherein:
the respective RF connection points to which the first through N-th RF power signals are coupled are located at successive positions on the plasma chamber electrode; and
Δθᵢ=i*360°/N for i=1 to N.

26. The method of claim 21, wherein:
the number of RF power signals and the number of RF connection points is four;
the respective RF connection points that are coupled to the first, second, third and fourth RF power signals are located at successive positions on the plasma chamber electrode; and
each of the phase offsets Φᵢ(t) is a time-varying function of a single phase modulation repetition frequency F such that:
Φᵢ(t)=Aᵢ*sin(Ft*360°−i*90°), for i=1, 2, 3 and 4; and
Aᵢ are predetermined values for i=1, 2, 3 and 4.

27. The method of claim 26, wherein:
the plasma chamber electrode is rectangular; and
the four RF connection points are positioned adjacent four respective corners of the plasma chamber electrode.

28. The method of claim 26, wherein:
the plasma chamber electrode has a rectangular perimeter with four sides; and
the four RF connection points are positioned adjacent to the respective centers of the four respective sides of the perimeter of the plasma chamber electrode.

29. The method of claim 21, wherein each of the phase offsets Φᵢ(t) is a time-varying function of first and second repetition frequencies F₁ and F₂ such that:
Φᵢ(t)*sin(F₁t*360°−Δθᵢ), for i=1 to N;
wherein Δθᵢ are predetermined values for i=1 to N; and
wherein, for i=1 to N, each Aᵢ(t) is a periodic function having a repetition frequency equal to F₂.

30. The method of claim 21, wherein:
the number of RF power signals and the number of RF connection points is four;
the respective RF connection points that are coupled to the first, second, third and fourth RF power signals are located at successive positions on the plasma chamber electrode; and
each of the phase offsets Φᵢ(t), for i=1, 2, 3 and 4, is a time-varying function of first and second distinct phase modulation repetition frequencies F₁ and F₂ such that:
Φ₁(t)=A₁ sin(F₁t*360°)
Φ₂(t)=A₂ sin(F₂t*360°)
Φ₃(t)=−Φ₁(t)
Φ₄(t)=−θ₂(t)

31. The method of claim 21, wherein:
the number of RF power signals and the number of RF connection points is four;
the respective RF connection points that are coupled to the first, second, third and fourth RF power signals are located at successive positions on the plasma chamber electrode;
the phase offset of the first RF power signal relative to the reference RF signal is a periodic function of time having a first repetition frequency;
the phase offset of the second RF power signal relative to the reference RF signal is a periodic function of time having a second repetition frequency different from the first repetition frequency;
the phase offset of the third RF power signal relative to the reference RF signal is minus one times the phase offset of the first power signal; and
the phase offset of the fourth RF power signal relative to the reference RF signal is minus one times the phase offset of the second power signal.

32. The method of claim 21, wherein:
the number of RF power signals and the number of RF connection points is four;
the respective RF connection points that are coupled to the first, second, third and fourth RF power signals are located at successive positions on the plasma chamber electrode; and
each of the phase offsets Φᵢ(t), for i=1, 2, 3 and 4, is a time-varying function of first and second distinct frequencies F₁ and F₂ and of first and second predetermined parameters A₁ and A₂ such that:
Φ₁(t)=A₁ sin(F₁t*360°)
Φ₂(t)=−Φ₁(t)
Φ₃(t)=Φ₂(t)+A₂ sin(F₂t*360°)
Φ₄(t)=Φ₁(t)+A₂ sin(F₂t*360°)

33. The method of claim 21, further comprising the step of:
coupling to the plasma chamber electrode an additional RF power signal having an RF frequency lower than the frequency of said reference RF signal.

34. The method of claim 21, further comprising the steps of:
producing said reference RF signal; and
coupling the reference RF signal to each RF power source.

35. The method of claim 21, further comprising the steps of:
producing a reference oscillator signal having a frequency different from said reference RF signal;
coupling the reference oscillator signal to each RF power source; and
each RF power source deriving its respective RF power signal from the reference oscillator signal.

36. A method for coupling RF power to a plasma chamber comprising the steps of:
providing a plasma chamber electrode having first, second and third RF connection points that are not collinear;
producing a first, second and third RF power signal, wherein each of the RF power signals has an RF frequency equal to a first frequency;
coupling the first, second and third RF power signals to the first, second and third RF connection points, respectively; and
coupling to the plasma chamber electrode an additional RF power signal having an RF frequency lower than said first frequency;
wherein the first and second RF power signals have a first phase offset and a second phase offset, respectively, relative to the third RF power signal, wherein the first phase offset and the second phase offset are distinct functions of time.
